(19) United States
(12) Patent Application Publication
(10) Pub. No.: US 2010/0209826 A1
(43) Pub. Date: Aug. 19, 2010

(54) Apparatus for processing photomask, methods of using the same, and methods of processing photomask

(76) Inventors: Sung-Hyuck Kim, Yongin-si (KR); In-Kyun Shin, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/656,747

(22) Filed: Feb. 16, 2010

(30) Foreign Application Priority Data
Feb. 13, 2009 (KR) 10-2009-0012063

(51) Int. Cl. G03F 1/00

(52) U.S. Cl. 430/5

(57) ABSTRACT

An apparatus and method for improving global flatness of a photomask is provided. The apparatus may include an adsorbing plate including vacuuming holes on one surface thereof, the adsorbing plate being adapted to adsorb the photomask thereon, a photomask supporting part including a plurality of supporting portions adapted to support the photomask and supporting arms on which the supporting portions are disposed, and a pressing plate including a pressing frame adapted to apply pressure to one surface of the photomask.

### BACKGROUND

1. Field

Exemplary embodiments relate to an apparatus for improving global flatness of a photomask used in a semiconductor fabrication process, methods for improving global flatness of a photomask using such an apparatus, and method for improving global flatness of a photomask.

2. Description of Related Art

As the degree of integration of semiconductor devices increases, techniques for fabricating a variety of semiconductor devices have been developed. Particularly, patterning techniques for forming fine patterns are rapidly improving. Among patterning techniques, a photolithography technique in which a photomask is a core component is commonly employed. Therefore, among techniques for improving and/or increasing a degree of integration of semiconductor devices, improved techniques for fabricating photomasks are desired.

### SUMMARY

Embodiments are therefore directed to apparatus and methods adapted to process or improve global flatness of a photomask, which substantially overcome one or more of the problems due to the limitations and disadvantages of the related art.

It is therefore a feature of an embodiment to provide apparatus for processing or improving global flatness of a photomask, and methods for improving global flatness of a photomask using such an apparatus.

It is therefore a separate feature of an embodiment to provide a method for processing or improving global flatness of a photomask.

At least one of the above and other features and advantages may also be realized by providing an apparatus for processing or improving global flatness of a photomask, the apparatus including an adsorbing plate including vacuuming holes on one surface thereof, the adsorbing plate being adapted to adsorb the photomask thereon, a photomask supporting part including a plurality of supporting portions adapted to support the photomask and supporting arms on which the supporting portions are disposed, and a pressing plate including a pressing frame adapted to apply pressure to one surface of the photomask.

At least one of the above and other features and advantages may also be separately realized by providing a method of processing or improving global flatness of a photomask using an apparatus for processing a photomask, including introducing a photomask into the apparatus, mounting the photomask on a photomask support included in the apparatus, fixing the photomask on an adsorbing plate included in the apparatus, the adsorbing plate including vacuuming holes on one surface thereof, the adsorbing plate being adapted to adsorb the photomask thereon, and pressing the photomask using a pressing plate included in the apparatus.

At least one of the above and other features and advantages may also be separately realized by providing a method of processing a photomask using an apparatus for improving global flatness of a photomask, the method including introducing a photomask into the apparatus, mounting the photomask on a photomask supporting part including a plurality of supporting portions adapted to support the photomask and supporting arms on which the supporting portions are disposed, fixing the photomask on an adsorbing plate including vacuuming holes and/or guiding portions arranged on one surface thereof, the adsorbing plate being adapted to adsorb the photomask thereon, and pressing the photomask using a pressing plate including a pressing frame adapted to apply pressure to one surface of the photomask.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1A illustrates a conceptual perspective view of an exemplary embodiment of an apparatus for improving global flatness;

FIG. 1B illustrates a cross-sectional view of the apparatus of FIG. 1A;

FIGS. 2A, 2B, 2C, 2D, 2E, and 2F illustrate conceptual views of various exemplary embodiments of adsorbing plates;

FIGS. 3A, 3B, 3C, and 3D illustrate conceptual views of exemplary embodiments of pressing plates; and

FIG. 4 illustrates a flowchart of an exemplary method for improving global flatness of a photomask being processed.

### DETAILED DESCRIPTION

Korean Patent Application No. 10-2009-0012063, filed on Feb. 12, 2009, in the Korean Intellectual Property Office, and entitled: “Apparatus for Improving Global Flatness of Photomask and Method for Using the Same,” is incorporated by reference herein in its entirety.

Exemplary embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when an element is referred to as being “on” another element, it can be directly on the other element, or intervening elements may also be present. In addition, it will also be understood that when an element is referred to as being “between” two elements, it can be the only element between the two elements, or one or more intervening elements may also be present.

Further, in the following description, a photomask is assumed to have a regular square shape. Accordingly, in the following description, it may be assumed that components of exemplary embodiments for improving global flatness of a photomask, e.g. plates, may be formed in the shape of a regular square. However, embodiments are not limited thereto. Further, in the following descriptions, a determination of global flatness of a photomask may correspond to an amount of bending of the photomask. Like reference numerals refer to like elements throughout the specification.

While research on forming a pattern on a photomask as fine as possible has been conducted for quite a while, and finer and finer patterns are being formed on a wafer using a photomask, the result is sometimes unsatisfactory. The applicants determined that the unsatisfactory results may at least, in part, be due to conditions of a photomask, e.g., flatness. After examining global flatness of a number of photomask substrates, it was determined that global flatness conditions of the photomask may lead to errors in patterns to be formed therewith. It was noted, e.g., that global flatness as a result of, e.g., bending of a photomask during processing of the photomask and/or from repeated use of the mask, may lead to errors in patterns formed therewith. Further, often errors in a resulting pattern may only be determined by checks performed after the photomask is employed. In the following description, embodiments of apparatus and methods of improving global flatness of a photomask being processed are described and may be advantageous in reducing and/or eliminating error in patterns formed using such photomasks.

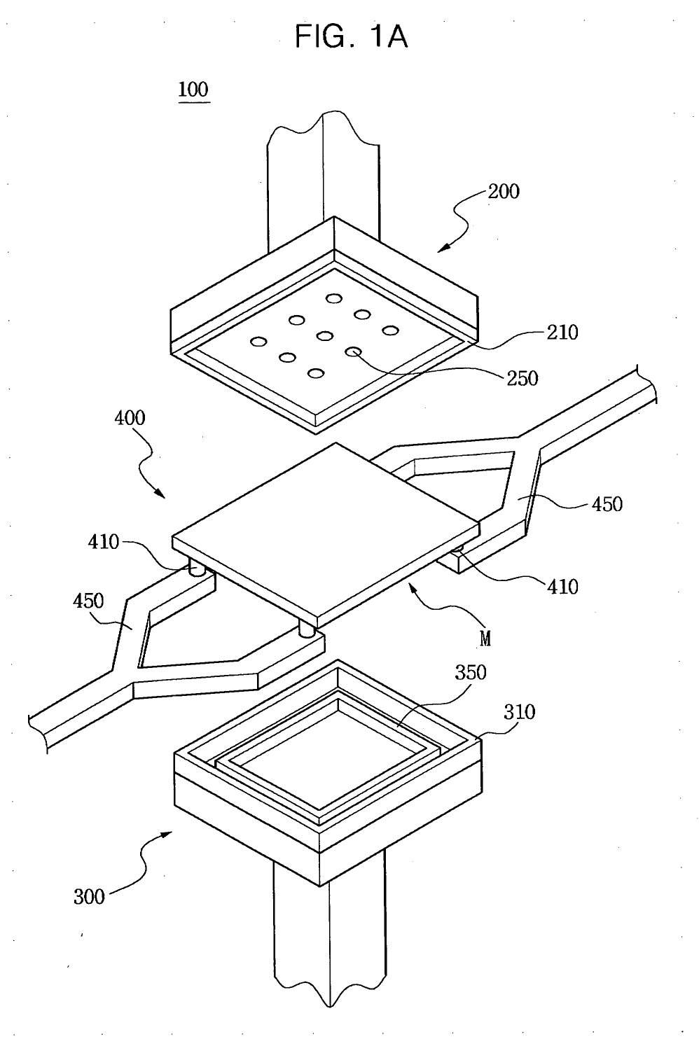

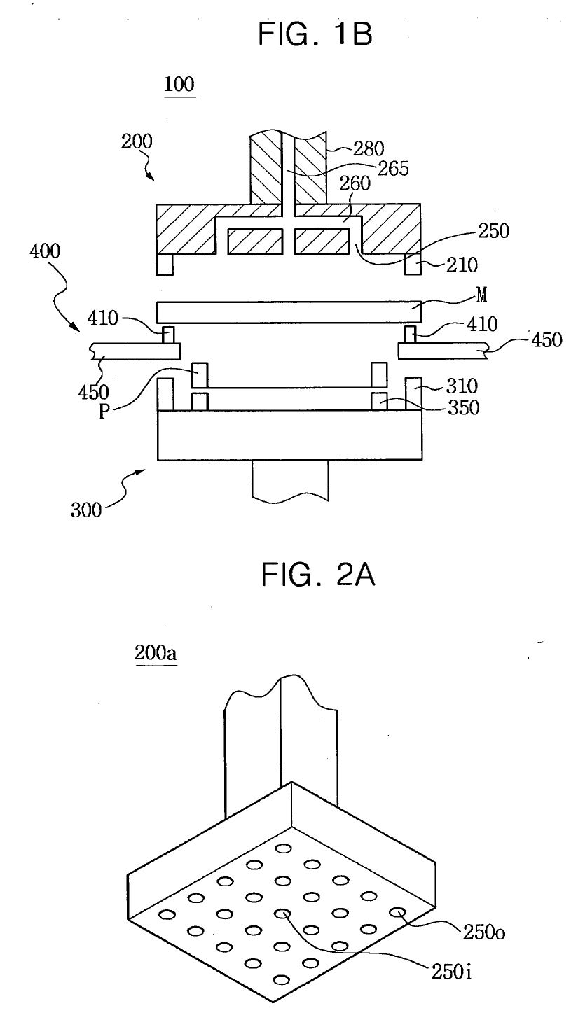

FIG. 1A illustrates a conceptual perspective view of an exemplary embodiment of an apparatus 100 for improving global flatness of a photomask M. FIG. 1B illustrates a cross-sectional view of the apparatus of FIG. 1A.

Referring to FIGS. 1A and 1B, the apparatus 100 for processing or improving the global flatness of the photomask M may include an adsorbing plate 200, a pressing plate 300, and a photomask supporting part 400. The adsorbing plate 200 may include adsorbing dams 210 and vacuuming holes 250. The pressing plate 300 may include pressing dams 310 and pressing frames 350. The photomask supporting part 400 may include a plurality of supporting portions 410, e.g., four supporting portions 410 in contact with a bottom surface of the photomask M and supporting arms 450.

The adsorbing plate 200 may serve to fix a position of the photomask M relative to the apparatus 100. More particularly, e.g., when the photomask M receives pressure from the pressing plate 300, the adsorbing plate 200 may fix the photomask M to prevent movement of the photomask M. In some embodiments, the adsorbing plate 200 may be positioned over the photomask M. The adsorbing plate 200 may include components for fixing the photomask M, e.g. vacuuming holes, clampers and/or fixing pins. In this description, the exemplary adsorbing plate 200 includes the vacuuming holes 250; however, embodiments are not limited thereto. When the adsorbing plate 200 includes the vacuuming holes 250, it may fix the photomask M in position and may also improve the global flatness of the photomask M using suction forces of the vacuuming holes 250.

The vacuuming holes 250 may be formed in various shapes and may distributed on the adsorbing plate 200 in various ways. The adsorbing plate 200 may include vacuum suction tubes 260 for providing vacuum to the vacuuming holes 250. Moreover, the adsorbing plate 200 may further include an adsorbing plate fixing rod 280 to which the adsorbing plate 200 is fixed and the adsorbing plate fixing rod 280 may further include a vacuum suction passage 265 formed therein. In the drawings, the vacuuming holes 250 are evenly arranged on the adsorbing plate 200, but they may be arranged in various ways. The adsorbing plate 200 will be described later in more detail.

The pressing plate 300 may be positioned below the photomask M. That is, the pressing plate 300 may apply upward pressure to a lower surface of the photomask M which faces down, while an upper surface of the photomask M may be pressed and/or pulled up against, i.e., fixed in a position relative to, the adsorbing plate 200.

The pressing plate 300 may include the pressing frames 350 that may physically apply pressure to the photomask M. The pressing frames 350 may be formed in the shapes of dams protruding from the pressing plate 300. The pressing dams 310 may serve to align the photomask M and/or may serve to align a pellicle P during a process of attaching the pellicle P.

The pressing frames 350 may be in contact with outer portions of seal pattern regions formed on the photomask M and may apply pressure thereto. Applying pressure may be understood as physically pressing a corresponding portion using a force. The pressing frames 350 may be integrally formed as a single frame or may include a plurality of portions. In embodiments in which the pressing frames include a plurality of portions, one, some or all of the portions may independently apply a respective pressure to the photomask M. In embodiments in which the pressing frames 350 are integrally formed, the pressing frame 350 may apply uniform pressure to the respective portions of the photomask M in contact therewith. However, even when the pressing frame 350 applies uniform pressure, the pressure received by the photomask may be different at some different portions and/or each contact portion thereof as a result of, e.g., global flatness of the photomask M.

For example, a portion of the photomask M having bad global flatness, i.e., a severely bent portion or a protruding portion, may receive a relatively stronger pressure. By employing the pressing frames 350 including a plurality of portions, each of the plurality of portions of the pressing frames 350 may selectively apply a pressure based on a condition, e.g., flatness, of the respective portion of the photomask M to which the portion of the pressing frame 350 is to apply pressure.

The pressing frames 350 may be formed in various shapes. In the exemplary embodiments of the pressing frames 350 illustrated in the accompanying figures, the pressing frames 350 are illustrated as being in the shape of a quadrangle. It should be understood that embodiments are not limited to such a shape.

The pressing frames 350 may serve a plurality of functions. For example, referring to FIG. 1B, in some embodiments, the pressing frames 350 may be formed, e.g., in the shape of a quadrangle, and may serve to apply pressure to the pellicle P. The pressing frames 350 will be described later in further detail.

The photomask supporting part 400 may support the photomask M on sides or edges of the photomask M. The photomask supporting part 400 may include the plurality of supporting portions 410 and the supporting arms 450. The supporting portions 410 may respectively contact a respective portion of the photomask M. The supporting portions 410 may be arranged on the supporting arms 450. In the exemplary embodiment of FIGS. 1A and 1B, the apparatus includes two supporting arms 450, each of the supporting arms includes two of the supporting portions 410 arranged thereon, and each of the supporting portions 410 contacts a portion of a lower surface of the photomask M. More particularly, referring to FIGS. 1A and 1B, the exemplary supporting portions 410 contact respective portions of outer portions of the photomask M. However, embodiments are not limited thereto and the photomask supporting part 400 may be implemented in various forms.

Although the pellicle P is illustrated in FIG. 1B, embodiments may not be employed in conjunction with a pellicle. That is, while in some embodiments, when the pressing frames 350 may apply pressure to the photomask M through the pellicle P, embodiments are not limited thereto. For example, in some embodiments, a cushion that may serve to protect the respective surface of the photomask M being pressed may be used, or no cushion may be used.

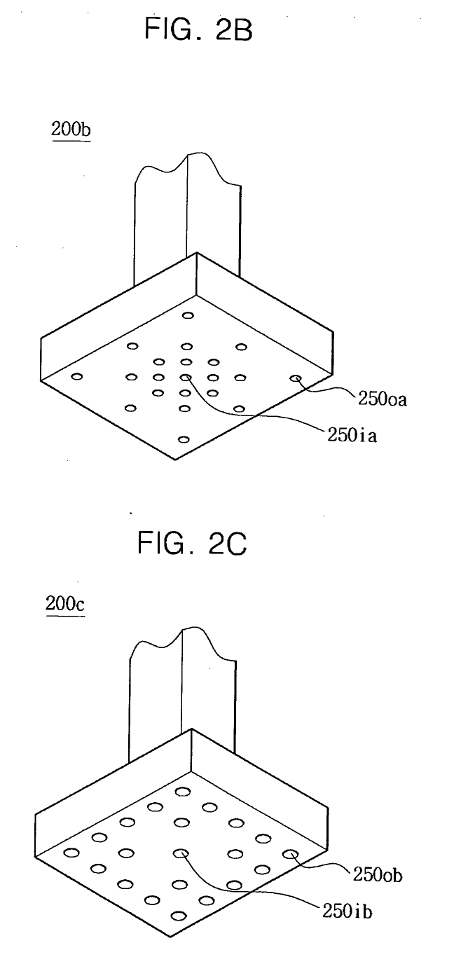

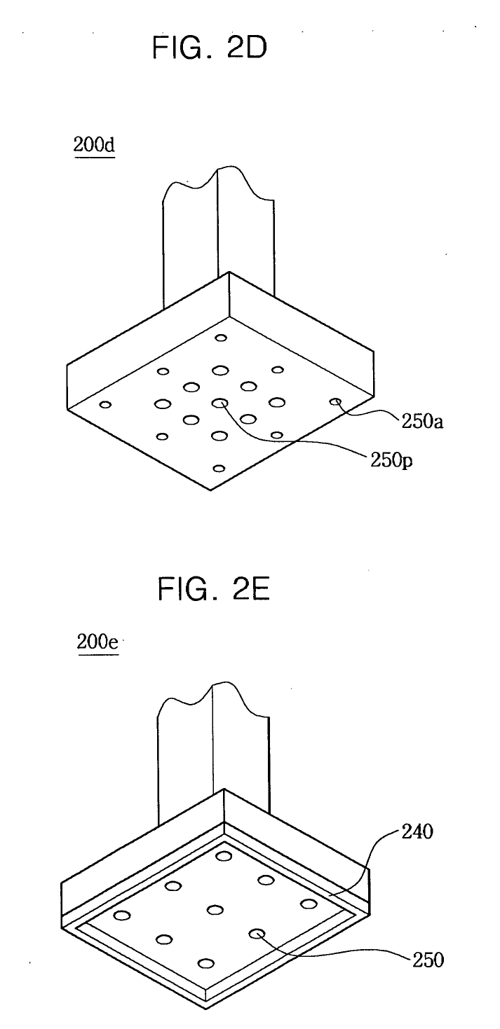

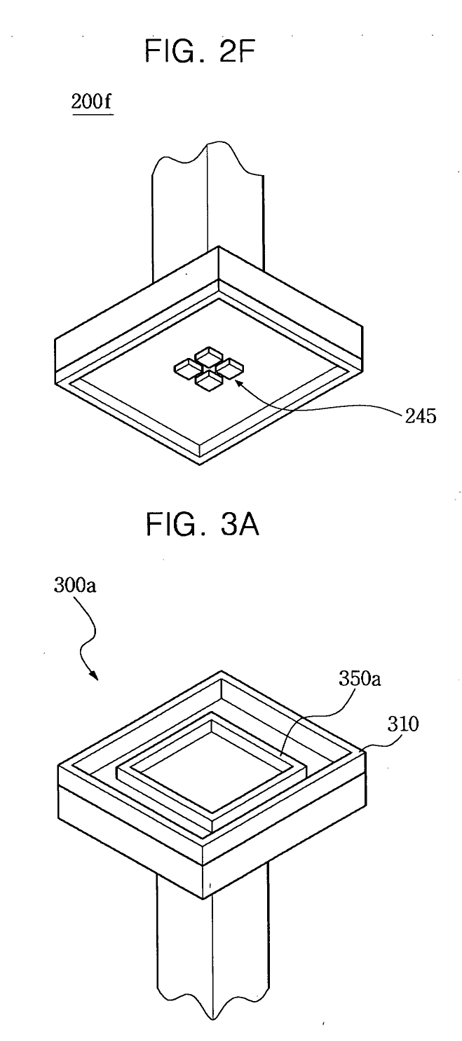

FIGS. 2A, 2B, 2C, 2D, 2E, and 2F illustrate conceptual views of various exemplary embodiments of adsorbing plates.

Referring to FIG. 2A, an adsorbing plate 200a may include vacuuming holes 250i, 250o evenly arranged on one entire surface thereof. As in this example embodiment, when the vacuuming holes 250i, 250o are evenly arranged on the entire adsorbing plate 200a, global flatness of a photomask M may be improved according to methods for controlling suction forces of the respective vacuuming holes 250i, 250o. More particularly, when the suction forces of the vacuuming holes 250i, 250o are entirely uniform, the adsorbing plate 200a may only serve to fix the photomask M in position. However, when the vacuuming holes 250i, 250o may be selectively controlled to have different suction forces in some or all of vacuuming holes 250i, 250o based, e.g., on the position of the vacuuming holes 250i, 250o and/or a condition, e.g., flatness, of the photomask M, a physical pressure may be selectively applied to one or more portions of the photomask M. That is, the suction forces of the vacuuming holes 250i, 250o in specific positions may be controlled by a plurality of vacuum controllers so that one or more specific portions of the photomask M may receive physical pressure. More specifically, e.g., when inner vacuuming holes 250i arranged in inner portions adsorb the photomask M with a stronger suction force than outer vacuuming holes 250o arranged in an outer portion, the inner portion of the photomask M may receive a pressure in the direction of the adsorbing plate 200a. On the other hand, e.g., when the outer vacuuming holes 250o arranged in outer portions adsorb the photomask M with a stronger suction force than the inner vacuuming holes 250i arranged in the inner portion, the outer portion of the photomask M may receive pressure in the direction of the adsorbing plate 200a.

In such embodiments in which different vacuuming holes, e.g., the inner vacuuming holes 250i and the outer vacuuming holes 250o, may selectively apply a different suction force, a same or a plurality of vacuum controllers (not shown) may be employed. For example, by applying a suction force in a step-wise manner, a single vacuum controller may be employed to apply the different suction forces of the inner vacuuming holes 250i and the outer vacuuming holes 250o. Further, various techniques may be employed, irrespective of whether one or more vacuum controllers are employed, to selectively control the respective suction forces for the different vacuuming holes 250, e.g., for the inner vacuuming holes 250i and the outer vacuuming holes 250o. For example, a suction force may be split accordingly based on suction force information by adjusting a size of respective vacuum suction tubes 260 or vacuum suction passages 265 connected to the inner vacuuming holes 250i and the outer vacuuming holes 250o. Further, e.g., in the exemplary embodiment illustrated in FIG. 2A, the plurality of the inner vacuuming holes 250i and the outer vacuuming holes 250o are uniformly arranged on the adsorbing plate 200a. However, embodiments are not limited thereto, and more or fewer ones of the inner and outer vacuuming holes 250i and 250 may be arranged in various ways.

Embodiments of the adsorbing plate 200a including one or more of the features described above may be advantageous by enabling a global flatness of the respective photomask M being processed to be improved. Such an improvement in global flatness of the photomask M being processed may result from the adsorbing plate 200a even in a state where a pressing plate 300 does not apply pressure to the photomask M.

Referring to FIG. 2B, an adsorbing plate 200b according to a second exemplary embodiment of may include inner vacuuming holes 250ia and outer vacuuming holes 250oa. The inner vacuuming holes 250ia may be mostly arranged towards, e.g., central or inner portions of the adsorbing plate 200b. The outer vacuuming holes 250oa may be arranged along a boundary of the adsorbing plate 200b. More particularly, the exemplary construction of FIG. 2B may concentrate a suction force at an inner portion of the photomask M being processed and may be effective for improving global flatness of the photomask M. As a result of the arrangement of the inner vacuuming holes 250ia and the outer vacuuming holes 250oa on the adsorbing plate 200b, the global flatness of the photomask M being processed may be improved even when the suction forces of the inner vacuuming holes 250i and the outer vacuuming holes 250o may be the same. That is, the suction forces of the inner vacuuming holes 250i and the outer vacuuming holes 250o need not be controlled through a special controller and all of the inner vacuuming holes 250i and the outer vacuuming holes 250o may be controlled through one vacuum controller and under the same conditions. It should be understood, however, even when employing the adsorbing plate 200b of FIG. 2B, the suction forces of the inner vacuuming holes 250ia and the outer vacuuming holes 250oa may be selectively controlled. The adsorbing plate 200b of FIG. 2B may be employed to improve global flatness of the photomask M being processed. For example, in a state where the pressing plate 300 does not apply pressure to the photomask M, the adsorbing plate 200b may improve the global flatness of the photomask M being processed.

Referring to FIG. 2C, an adsorbing plate 200c according to a third exemplary embodiment may include outer vacuuming holes 250ob and inner vacuuming holes 250ib. The outer vacuuming holes 250ob may be arranged, e.g., along outer portions or a boundary of the adsorbing plate 200c. The inner vacuuming holes 250ib may be arranged in a pattern towards an inner portion of the adsorbing plate 200c. The exemplary adsorbing plate 200c of FIG. 2C may concentrate a suction force at outer portions of the photomask M and may be effective for improving global flatness of the photomask M being processed. That is, the exemplary adsorbing plate 200c of FIG. 2B may be employed to improve global flatness of the photomask M being processed even if the suction forces of the inner vacuuming holes 250ib and the outer vacuuming holes 250ob are the same. As in the exemplary embodiment of FIG. 2B, the suction forces of the inner vacuuming holes 250ib and the outer vacuuming holes 250ob need not be controlled through a special controller and all of the inner vacuuming holes 250ib and the outer vacuuming holes 250ob may be controlled through one vacuum controller. However, embodiments are not limited thereto and, e.g., more than one vacuum controller may be employed and/or different suction forces may be applied. The adsorbing plate 200c of FIG. 2C may be employed to improve global flatness of the photomask M being processed. For example, in a state where the pressing plate 300 does not apply pressure to the photomask M, the adsorbing plate 200c may improve the global flatness of the photomask M being processed.

Referring to FIG. 2D, an adsorbing plate 200d according to a fourth exemplary embodiment may include adsorbing vacuuming holes 250a for adsorbing and pressing vacuuming holes 250p for pressing. The adsorbing vacuuming holes 250a and the pressing vacuuming holes 250p may be are arranged on one surface of the adsorbing plate 200d. The adsorbing vacuuming holes 250a and the pressing vacuuming holes 250p may be classified and optimized for a plurality of different functions. For example, the adsorbing vacuuming holes 250a may serve to fix a photomask M to the adsorbing plate 200d and the pressing vacuuming holes 250p may serve to apply pressure to the photomask M fixed to the adsorbing plate 200d. In the exemplary embodiment of FIG. 2D, the two vacuuming holes 250a and 250p are illustrated as having different sizes to be easily visually distinguishable. However, relative sizes and distributions of the adsorbing vacuuming holes 250a and pressing vacuuming holes 250p are independent of each other.

Referring to FIG. 2E, an adsorbing plate 200e according to a fifth exemplary embodiment may include one or more photomask supporting guides 240 and the vacuuming holes 250 (see, e.g., FIG. IA). The photomask supporting guide 240 may be integrally formed or may include a plurality of pieces. The photomask supporting guide 240 may be formed in the shape of a fence and/or may be disposed on an outer portion of the adsorbing plate 200e. Referring to FIG. 2E, the photomask M (not shown) to be processed may be adsorbed by the adsorbing plate 200e, and respective portions of the photomask M may contact respective surfaces of the photomask supporting guides 240 and/or may be fixed within the photomask supporting guides 240. The photomask supporting guides 240 may move side to side, e.g., in the left-right direction. As the photomask supporting guides 240 move in the left-right direction, the photomask supporting guides 240 may align the photomask M in a predetermined position, e.g., exact position, relative to the adsorbing plate 200e. In embodiments, one, some or all of the photomask supporting guides 240 may be moveable, and it should be understood, e.g., that not all of the photomask supporting guides 240 need to move. More particularly, e.g., by employing at least two photomask supporting guides 240 that are oriented, e.g., at right angles to each other, and are moveable, an operation for aligning the photomask M may be sufficiently performed. Although not illustrated, the photomask supporting guides 240 may include, e.g., a hinge-type or nail-type clamper that may clamp the photomask M. In embodiments of the apparatus 100 employing the adsorbing plate 200e, the adsorbing plate 200e may support an outer portion of the photomask M and the pressing plate 300 may apply pressure to an inner portion of the photomask M, and may thereby improve global flatness of the photomask M being processed. While vacuuming holes 250 are illustrated in FIG. 2D, in some embodiments, the vacuuming holes 250 may not be provided. Further, while vacuuming holes 250 are illustrated in FIG. 2D, other exemplary vacuuming holes, e.g., 250o, 250i, 250oa, 250ia, 250ob, 250ib, may be employed and/or other features described herein, e.g., photomask supporting portions 245 of FIG. 2F, may be employed.

Referring to FIG. 2F, an adsorbing plate 200f according to a sixth exemplary embodiment may include one or more photomask supporting portions 245. The photomask supporting portions 245 may be formed in the shape of a mesa. The photomask supporting portions 245 may be disposed on an inner portion of the adsorbing plate 200f. When the adsorbing plate 200f is employed by the apparatus 100 of FIG. 1A, the adsorbing plate 200f may support, e.g., an inner portion of the photomask M and the pressing plate 300 may apply pressure to, e.g., an outer portion of the photomask M, and may thereby improve global flatness of the photomask M being processed. Although four supporting portions 245 having a same size and shape are illustrated in FIG. 2F, embodiments are not limited thereto, e.g., five or more supporting portions 245 may be provided. Further, although not shown, the adsorbing plate 200f may include a clamper, e.g., on an outer portion thereof The adsorbing plate 200f may support, e.g., an inner portion of the photomask M being processed while the pressing plate 300 applies a pressure to the periphery of the inner portion of the photomask M or the outer portion thereof, and the global flatness of the photomask M being processed may thereby be improved.

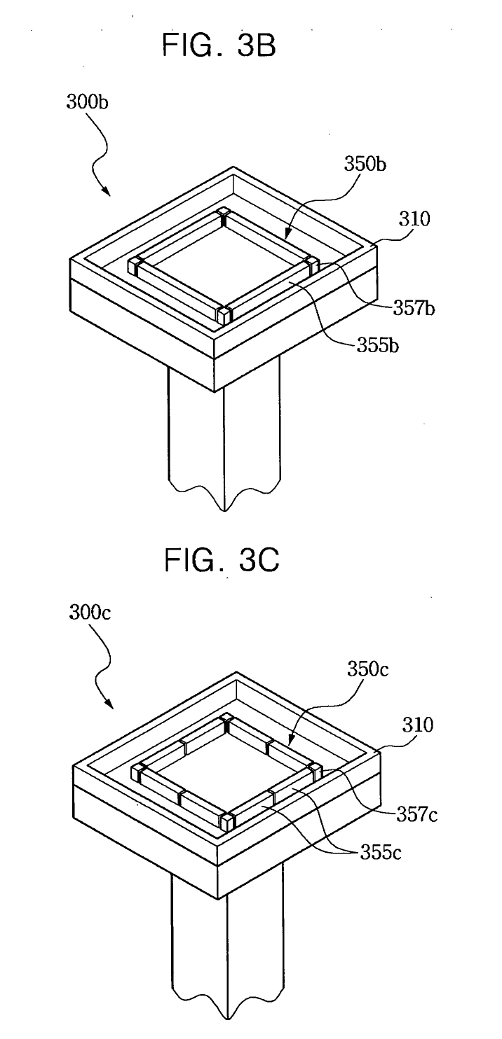

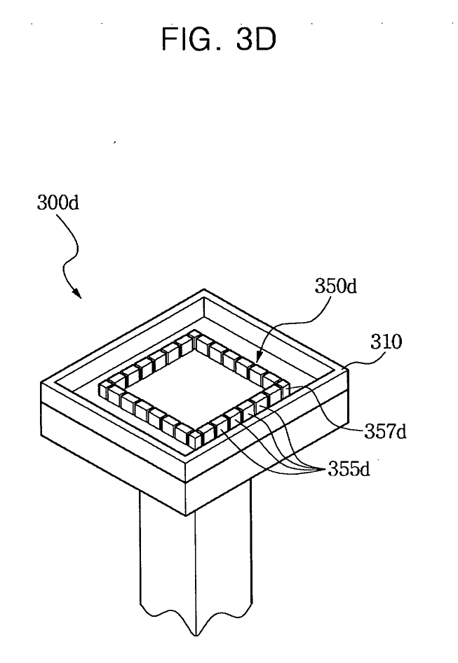

FIGS. 3A, 3B, 3C, and 3D illustrate conceptual views of exemplary embodiments of pressing plates.

Referring to FIG. 3A, a pressing plate 300a according to a first exemplary embodiment may include an integrated pressing frame 350a. The integrated pressing frame 350a may be disposed on one surface of the pressing plate 300a. The pressing frame 350a may be integrally formed and may enable a uniform force to be transferred to respective portions of the pressing plate 350a and a pressure may be applied to a surface of the photomask M being processed. In the exemplary embodiment illustrated in FIG. 3A, the pressing frame 350a is formed in the shape of a quadrangle, but embodiments are not limited thereto, e.g., the pressing frame 350 may be formed in various shapes.

Referring to FIG. 3B, a pressing plate 300b according to a second exemplary embodiment may include quadrangular pressing frames 350b. The quadrangular pressing frames 350b may include, e.g., side pressing portions 355b and corner pressing portions 357b. More particularly, referring to the exemplary embodiment of FIG. 3B, the quadrangular pressing frames 350b may include four of the side pressing portions 355b and four of the corner pressing portions 357b, i.e., one of the side pressing portions 355b on each side and independent corner pressing parts 357b on each corner, disposed on one surface of the pressing plate 300b. By employing the respective side pressing portions 355b and the respective corner pressing portions 357b, each of the respective side pressing parts 355b and/or the respective corner pressing portions 357b may be individually controlled. That is, while the side pressing portions 355b and the corner pressing portions 357b may be controlled to supply a uniform pressure, instead of uniform pressure, the side pressing portions 355b and/or the corner pressing portions 357b may be selectively controlled, e.g., to apply a stronger and/or weaker pressure to one or more different portions. In embodiments, although not shown, a pressure transfer portion that may transfer pressure to the respective pressing portions 355b and 357b of the pressing frames 350b may be disposed on the pressing plate 300b and may be independently controlled by one or more pressure controllers.

Referring to FIG. 3C, a pressing plate 300c according to a third exemplary embodiment may include pressing frames 350c divided into plural portions. The pressing frames 350c may be disposed on one surface of the pressing plate 300c. The pressing frames 350c may include, e.g., at least two side pressing portions 355c and corner pressing portions 357c on a same side. More particularly, as shown in the exemplary embodiment of FIG. 3C, the pressing plate 300c may include at least two side pressing portions 355c along each side of the pressing frames 350c. Relative to the exemplary pressing plate 300b of FIG. 3B, by employing a plurality of side pressing portions along at least one side of the pressing frames 350c of the pressing plate 300c of FIG. 3C, pressure exerted by the pressing frames 350c may be more accurately controlled to improve global flatness of the photomask M being processed.

Referring to FIG. 3D, a pressing plate 300d according to a fourth exemplary embodiment may include pressing frames 350d divided into a plurality of point portions 355d. The pressing frames 350d may be disposed on one surface of the pressing plate 300d. The pressing frames 350d may include a plurality of independent pressing portions 355d, e.g., point-shaped pressing portions, on each side and independent corner pressing portions 357d on each corner. More particularly, e.g., one, some or all sides of the pressing frame 350d may each include more than two of the plurality of independent pressing portions 355d. The pressing plate 300d may more finely and accurately perform a process than the pressing plates 300b and 300c of the second and third example embodiments.

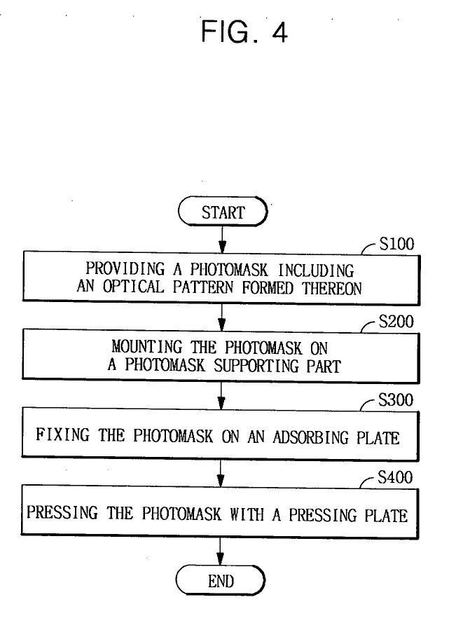

FIG. 4 illustrates a flowchart of an exemplary method for improving global flatness of the photomask M to be processed. Exemplary methods for improving global flatness of a photomask using an apparatus for improving global flatness of the photomask M will be described with reference to FIG. 1B and 4. The apparatus employed may include, e.g., any combination of the features described above with regard to FIGS. 1A, 1B, 2A to 2F, and 3A through 3D.

Referring to FIG. 4, the global flattening method may include providing the photomask M to be processed during S100. The photomask M may include an optical pattern formed thereon, e.g., on one surface thereof. In embodiments in which a pellicle is employed, the pellicle P may not be attached to the photomask M or if the pellicle P is attached to the photomask M, the pellicle P may be detached therefrom.

During S200, the photomask M may be mounted onto the photomask supporting part 400. More particularly, the photomask M may be mounted onto the photomask supporting part 400 such that the surface with the optical pattern formed thereon (the pattern-formed surface) may face the pressing plate 300, e.g., downward. As discussed above, the photomask supporting part 400 may include the supporting portions 410 and the supporting arms 450. The photomask M may be placed on the supporting portions 410 and the supporting portions 410 may be supported by the supporting arms 450.

During S300, the photomask M may be temporarily fixed, i.e., adsorbed, to the adsorbing plate 200. More particularly, e.g., a surface of the photomask M on which the optical pattern is not formed (the pattern-unformed surface) may be closely attached to the adsorbing plate 200. The adsorbing plate 200 may vacuum-adsorb, e.g., the pattern-unformed surface of the photomask M using, e.g., vacuuming holes 250, as described above with reference to FIGS. 2A through 2F.

During S400, the pressing plate 300 including the pressing frame 350 may be lifted so that the pressing frame 350 may contact the pattern-formed surface of the photomask M. In some embodiments, a cushion (not shown) may be interposed between the pressing frame 350 and the pattern-formed surface of the photomask M. In some embodiments, movement of the pressing frame 350 toward the photomask M may be performed with a process for attaching the pellicle P to the pattern-formed surface of the photomask M. More particularly, in such embodiments, the pellicle P may be put on the pressing frame 350 and the pressing plate 300 may be moved, e.g., lifted, so that the pellicle P and the surface of the photomask M may contact each other. Thereafter, in such embodiments, a lifting force of the pressing plate 300 may be transferred to the surface of the photomask P through the pressing frame 350 and the cushion or the pellicle P. As a result, the global flatness of the photomask M may be improved, and the global flattening method may end.

Embodiments of the apparatus, e.g., 100 of FIGS. 1A and 1B, for improving the global flatness of photomasks may perform a process for improving global flatness of a photomask but also a process for mounting a pellicle on the photomask. In embodiments in which the pellicle P is to be mounted, a pressing frame may be formed to have shape and/or size similar to a shape of the pellicle P. For example, as illustrated in the accompanying Figures, the pellicle P mounted on the pattern-formed surface of the photomask M and the pressing frame may have the shape of a quadrangle. When the shape and size of the pressing frame are the same and/or similar to the shape and/or size of the pellicle, a process for mounting the pellicle on the pattern-formed surface of the photomask M may be more simply carried out, e.g., may be carried out during a same process. Thus, a size and/or shape of the pressing frame may be determined based on whether a pellicle is to be mounted. However, embodiments are not limited thereto. For example, if the pellicle P is not to be mounted on the photomask, a size and/or shape of the pressing frame may be determined based on other considerations, e.g., size of apparatus, size and/or shape of photomasks M to be processed, size and/or shape of the pressing plate 300, size and/or shape of adsorbing plate, e.g., 200, etc. More particularly, the pressing frame 350 may be formed in the shape of a circle or a polygon. Alternatively, the pressing frame 350 may be composed of a plurality of poles similar to points.

Embodiments of an apparatus for improving global flatness of a photomask may improve global flatness of a photomask using a simple process and may perform the process concurrently with another process such as, e.g., a pellicle attachment process, which may result in high quality and productivity of the photomask processed thereby.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims. For example, embodiments of a pressing frame may be formed in various shapes and may enable global flatness of a photomask to be improved by applying a physical force to a surface of the photomask being processed. Further, in embodiments, a position of one or more elements of an apparatus for improving global flatness of a photomask, e.g., the apparatus 100 of FIGS. 1A and 1B may be changed or reversed. For example, an adsorbing plate may be positioned below the photomask being processed and a pressing plate may be positioned over the photomask. Alternatively, e.g., a pressing plate and an adsorbing plate may be positioned to face each other in a lateral direction of the photomask. That is, respective components may be positioned in various locations, and are not limited to the positions illustrated in the accompanying Figures.

1. (canceled)

2. A method of processing of a photomask using an apparatus for processing a photomask, comprising:
introducing a photomask into the apparatus;
mounting the photomask on a photomask support included in the apparatus;
fixing the photomask on an adsorbing plate included in the apparatus, the adsorbing plate including vacuuming holes on one surface thereof, the adsorbing plate being adapted to adsorb the photomask thereon; and
pressing the photomask using a pressing plate included in the apparatus.

3. The method as claimed in claim 2, wherein the vacuuming holes comprise inner vacuuming holes arranged on an inner portion of the adsorbing plate and outer vacuuming holes arranged on an outer portion of the adsorbing plate.

4. The method as claimed in claim 2, wherein a number of the inner vacuuming holes is larger than a number of the outer vacuuming holes.

5. The method as claimed in claim 2, wherein the inner vacuuming holes are wider than the outer vacuuming holes.

6. The method as claimed in claim 2, wherein the photomask supporting part includes at least four supporting portions and at least two supporting arms.

7. The method as claimed in claim 2, wherein the pressing plate further comprises a pressing dam positioned on an outer portion thereof.

8. The method as claimed in claim 2, wherein the pressing frame comprises a plurality of pressing portions arranged in a quadrangular shape.

9. The method as claimed in claim 8, wherein the pressing portions include a plurality of side pressing portions and a plurality of corner pressing portions.

10. The method as claimed in claim 9, wherein the side pressing portions are divided into plural portions on a same side.

11. The method as claimed in claim 8, wherein pressures of each of the pressing portions are independently controlled.

12. The method as claimed in claim 2, wherein the pressing plate further comprises a pressing cushion disposed on the pressing frame.

13. The method as claimed in claim 2, wherein the adsorbing pate includes a plurality of supporting portions protruding from the one surface of the adsorbing plate.

14. The method as claimed in claim 13, wherein at least one of the supporting portions has a mesa shape.

15. The method as claimed in claim 13, wherein the supporting portions are arranged in an inner portion of the adsorbing plate.

16. The method as claimed in claim 13, wherein the adsorbing plate includes a plurality of supporting guides protruding from the adsorbing plate.

17. The method as claimed in claim 16, wherein the photomask supporting guides are disposed at the outer portions of the adsorbing plate.

18. The method as claimed in claim 17, wherein the photomask supporting guides form a fence-like structure disposed at the outer portions of the adsorbing plate.

19. The method as claimed in claim 14, wherein the photomask supporting guides are movable relative to the surface of the adsorbing plate and are adapted to contact respective sides of the photomask.

20. A method of improving global flatness of a photomask using an apparatus for processing a photomask, the method comprising:
introducing a photomask into the apparatus;
mounting the photomask on a photomask supporting part including a plurality of supporting portions adapted to support the photomask and supporting arms on which the supporting portions are disposed;
fixing the photomask on an adsorbing plate including vacuuming holes and/or guiding portions arranged on one surface thereof, the adsorbing plate being adapted to adsorb the photomask thereon; and
pressing the photomask using a pressing plate including a pressing frame adapted to apply pressure to one surface of the photomask.
